(19) United States
(12) Patent Application Publication
(10) Pub. No.: US 2007/0251759 A1
(43) Pub. Date: Nov. 1, 2007

(54) Bass speaker stand

(76) Inventor: Eric Neiman, Los Angeles, CA (US)

Correspondence Address: JAMES RAY & ASSOCIATES, 2640 PITCAIRN ROAD, MONROEVILLE, PA, 15146, US

(21) Appl. No.: 11/789,255

(22) Filed: Apr. 24, 2007

Related U.S. Application Data
(60) Provisional application No. 60/795,127, filed on Apr. 26, 2006.

(51) Int. Cl. H05K 5/00

(52) U.S. Cl. 181/156

(57) ABSTRACT

A sound speaker stand for reducing resounding sound producing vibration levels from traveling through one of a floor and a wall. The sound speaker stand comprises a frame member having a back side, a left side and a right side. Such support member is formed of a predetermined material. There is a platform member for holding the sound producing speaker. The platform member is disposed within the frame member, and a support arrangement that is engageable with the support member and with the platform member for suspending the platform member relative to the support member.

### CROSS REFERENCE TO RELATED APPLICATIONS

This application is closely related to and claims benefit from U.S. Provisional Application Ser. No. 60/795,127 filed Apr. 26, 2006.

### FIELD OF THE INVENTION

The present invention relates, in general, to a stand, and, more particularly, the present invention relates to a stand for holding a sound speaker capable of producing low bass tone sound waives and which raises the speaker up off of the floor and prevents speaker vibrations from spreading to another area.

### BACKGROUND OF THE INVENTION

Not all homeowners or renters living in areas surrounded by neighbors are respectful when listening to music at home. Sound systems with large speakers can emit waves a great distance and even if the volume is kept at a relatively low level, low bass tones can reverberate and send vibrations through a wall or floor.

This disturbance not only annoys neighbors but the distortion interrupts the quality of sound. The disturbance is far from a mere annoyance if the volume is not minimal but is played loudly. It is difficult for neighbors who are exposed to this kind of annoyance, particularly if the music is played for a prolonged period of time. Some times the user is not aware of how much of a disturbance the music and the vibrations can be to other people.

Thus, it would be advantageous if there were a mount that could hold the sound speaker capable of producing low bass tone sound waives and cradle it so as to lower the instances of interruptions and vibrations caused by the sound waves emitted from such speaker.

### SUMMARY OF THE INVENTION

The present invention provides a stand for holding a sound speaker capable of producing low bass tone sound waives. The sound speaker stand comprises a support member. Such support member is formed of a predetermined material. There is a platform member for supporting the sound speaker positioned on said platform member in a freestanding fashion. There is means which is engageable with the support member and with the platform member for dampening any externally resounding vibrations produced by the sound speaker and for preventing promulgation of these externally resounding vibrations to the support member. Thus, the externally resounding vibrations are prevented from traveling through a structure having the sound speaker stand positioned on.

### OBJECTS OF THE INVENTION

It is, therefore, one of the primary objects of the present invention to provide a stand for a sound speaker that eliminates or substantially reduces the effects of low bass tone waves being transmitted externally from the sound speaker through a wall or floor.

Another object of the present invention to provide a sound speaker stand in which the sound speaker is supported on a platform that is suspended from the support.

Still another object of the present invention to provide a sound speaker stand in which the platform is supported by wires.

Yet another object of the present invention to provide a sound speaker stand which will also reduce distortion of the sound.

A further object of the present invention to provide a sound speaker stand which dampens the effects of vibration on the quality of the sound produced by the sound speaker.

In addition to the various objects and advantages of the invention which have been described in some specific detail above it should be noted that various other objects and advantages of the present invention will become more readily apparent to those persons who are skilled in the relevant art from the following more detailed description, particularly when such description is taken in conjunction with the appended claims.

### BRIEF DESCRIPTION OF THE DRAWINGS

FIG. 1 is a perspective view of a sound speaker stand of the present invention with a sound speaker supported on the platform in an upright and freestanding position;

FIG. 2 is a top view of the sound speaker stand shown in FIG. 1;

FIG. 3 is a front view of the sound speaker stand shown in FIG. 1;

FIG. 4 is a cutaway view of the dowel, wire and clamp arrangement used to secure the wires to the platform member; and

FIG. 5 is a cutaway view of the dowel, wire and clamp arrangement used to secure the wires to the support member.

### BRIEF DESCRIPTION OF THE PRESENTLY PREFERRED AND VARIOUS ALTERNATIVE EMBODIMENTS OF THE INVENTION

Prior to proceeding to the more detailed description of the present invention, it should be noted that for the sake of clarity in understanding the invention, identical components with identical functions have been designated with identical reference numerals throughout the drawing Figures.

Now in reference to FIGS. 1-5, therein is shown a sound speaker stand, generally designated 10, of the present invention for supporting a sound speaker 2 which is capable of producing low bass tones. The sound speaker stand includes a support member 12 which is manufactured from a predetermined material. It is presently preferred for the support member 12 to be formed as a frame having a back side 14, a left side 16 and a right side 18. The predetermined material for forming the support member 12 is selected from wood, plastic, metal and any combinations thereof.

A platform member 20 is disposed within the support member 12, being such frame, for supporting the sound speaker 2 which is positioned on the platform member 20 in an upright and freestanding fashion. Preferably, the platform member 20 has a flat surface abutting a bottom surface of the sound speaker 2 and is formed of a material which is identical to the predetermined material of the support member 10.

There is means, generally designated as 30, which is engageable with the support member 10 and with the platform member 20 for dampening any externally resounding vibrations produced by the sound speaker 2 and for preventing promulgation of the externally resounding vibrations to the support member 10, whereby the externally resounding vibrations are prevented from traveling through a structure having the sound speaker stand 10 positioned on. Such structure is either a well known floor 4 or a wall 6.

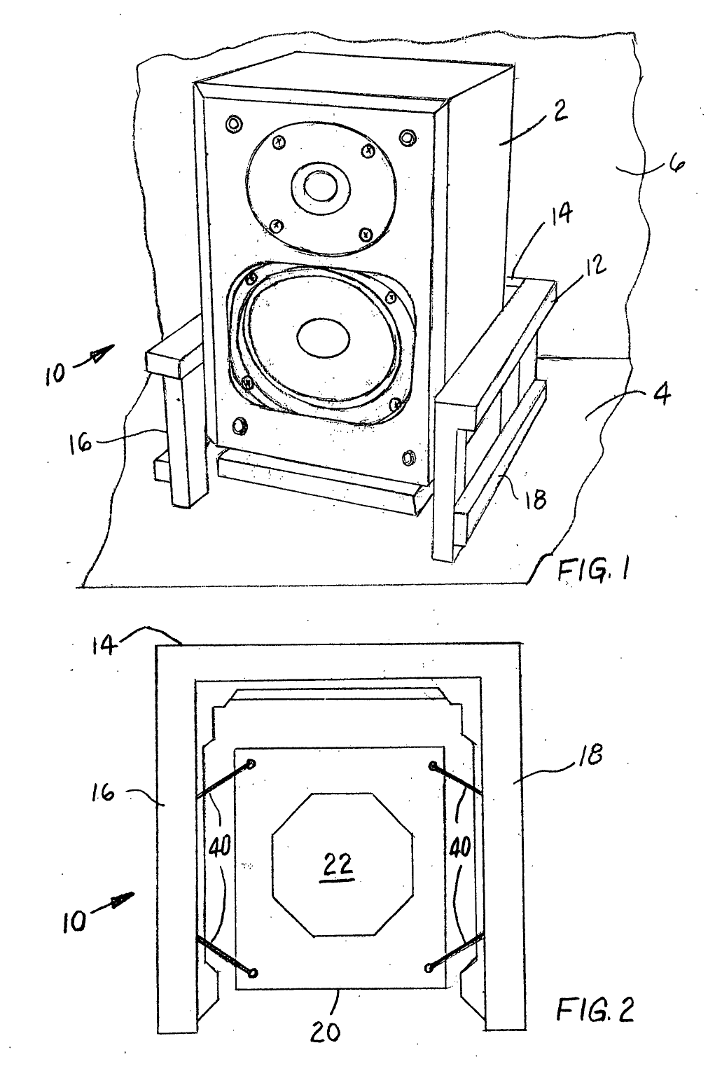

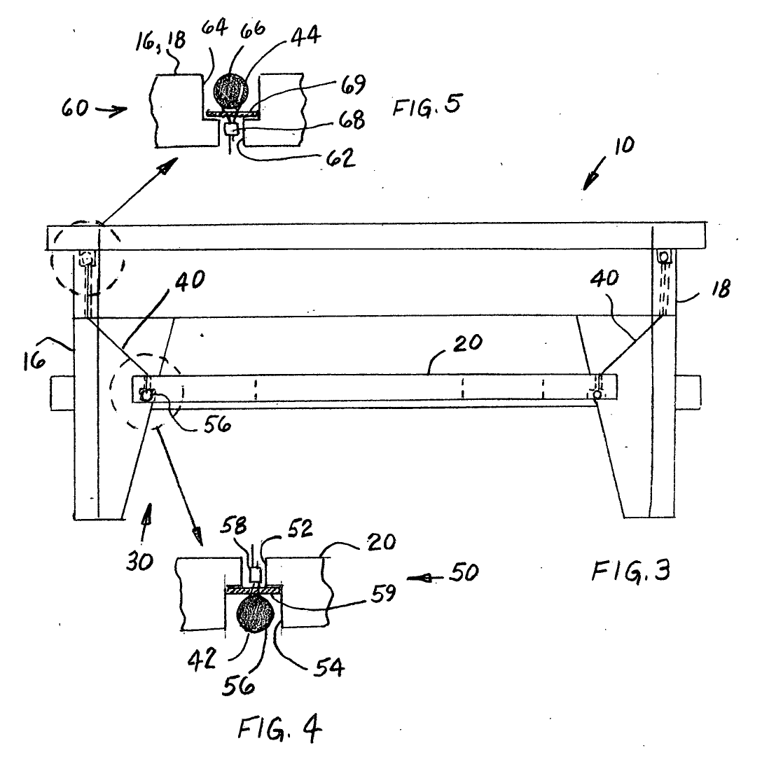

As is seen in FIGS. 2-3, the external vibration dampening means 30 suspends the platform member 20 relative to the support member 10. It will be appreciated that when the support member 10 is formed as a frame of FIG. 2, the platform member 20 is disposed and suspended within the frame.

Thus, when the sound speaker 2 is being played with a relatively high volume the low bass tone sound waves are not transferred through the floor 4 or through the wall 6. All or most of the reverberations caused by the sound of the sound speaker 2 are dampened by the suspended platform 20. A person living on a floor below the floor having the sound speaker 2 will appreciate the fact that he/she are not subjected to the thumping sound that would occur if the sound speaker 2 were positioned directly on the floor 4.

In the presently preferred embodiment of the invention, the external vibration dampening means 30 includes a plurality of wires 40, a plurality of first securing means, generally designated as 50, for securing one end 42 of each wire 40 to the platform member 20 and a plurality of second securing means, generally designated as 60, for securing another end 44 of each wire 40 with one of the left side 16 and the right side 18 of the support member 10. Each of the plurality of first securing means 50 includes an aperture 52 formed in the platform member 20 and a bore 54 which is axially aligned with the aperture 52 in a bottom surface of the platform member 20. An elongated member 56, for example such as a dowel rod, is positioned within the bore 54 with the one end 42 of the wire 40 encircling the elongated member 56. The wire 40 passes the platform member 20 from the top surface thereof. A swage clamp means 58 secures the encircled end 42 of the wire 40 in a conventional manner and is preferably hidden within the aperture 52 which is sized accordingly to receive such swage clamp means 58. If required, a washer 59 is positioned between a bottom of the bore 54 and the elongated member 56. The elongated member 56 is also preferably formed from a material which is identical to the predetermined material of the support member 12.

It is further presently preferred for each of the plurality of second securing means 60 to be identical to the first securing means 50. Accordingly, each of the second securing means 60 includes an aperture 62 formed in the one of the left side 16 and the right side 18 of the support member 12 and a bore 64 which is axially aligned with the aperture 62 in a bottom surface of such one of the left side and the right side of the support member 12. An elongated member 66 is positioned within the bore 64 with another end 44 of the wire 40 encircling the elongated member 66. A swage clamp means 68 secures the encircled end 34 of the wire 40 in a conventional manner and is preferably hidden within the aperture 62. If required, a washer 69 is positioned between a bottom of the bore 64 and the elongated member 66.

As is shown in FIG. 2, the platform member 20 is supported in a suspending fashion at positions that are closely adjacent each corner thereof. Therefore, four wires 30 are employed in the present invention. The wires 40 are positioned in a fashion that provides clearance between each wire 40 and the sound speaker 2.

It will be understood that the degree of dampening effort partially depends on the length of the wires 40 with longer wires 40 resulting in increased dampening effect. Therefore, the height of the support member 12 and corresponding lengths of the wires 40 is selected to provide desired degree of dampening based on the frequency of the low bass tone sound waves produced and emitted by the sound speaker 2 of a particular type and based on the environment wherein the present invention is used. It has been also found that the separation between the wire 40 and the elongated member 56, 66 further increases the dampening effort of the sound speaker stand 10.

The sound speaker stand 10 further includes means for dampening any internally resounding vibrations produced by the sound speaker 2. It is presently preferred for this internal vibration dampening means to include an aperture 22 which is formed in the platform member 20 and which is disposed beneath and generally aligned with the bottom surface of the sound speaker 2. By way of the example only of FIGS. 2, the aperture 22 is shown as having octagonal shape, although the present invention contemplates that other shapes of the aperture 22 may be employed in the present invention.

Thus, when the sound speaker 2 is being played with a relatively high volume the vibrations caused by the low bass tone sound waves are absorbed by the suspended platform member 20 thus dampening such vibrations and preventing their promulgation to the floor 4 or the wall 6 as well as preventing vibrations to resonate back to the sound speaker 2 and affect the quality of the produced sound.

Although the present invention has been shown in terms of the support member 12 being formed as a frame having two sides and the back, it will be apparent to those skilled in the art, that the present invention may be applied to other forms of the support member. For example, the support member 12 may be simply provided as a pair of freestanding side members 16, 18 or a single freestanding back member 14.

Furthermore, the platform member 20 which is illustrated as being formed from a unitary member having a generally flat surface may be formed as a hollow frame supporting the sound speaker 2 at a peripheral edge of the bottom surface thereof.

Thus, the present invention has been described in such full, clear, concise and exact terms as to enable any person skilled in the art to which it pertains to make and use the same. It will be understood that variations, modifications, equivalents and substitutions for components of the specifically described embodiments of the invention may be made by those skilled in the art without departing from the spirit and scope of the invention as set forth in the appended claims.

I claim:

1. A sound speaker stand for a sound speaker capable of producing low bass tones, said sound speaker stand comprising:
(a) a support member formed of a predetermined material and having a predetermined shape;
(b) a platform member for supporting the sound speaker positioned on said platform member in a freestanding fashion; and
(c) means engageable with said support member and with said platform member for dampening any externally resounding vibrations produced by the sound speaker and for preventing promulgation of said externally resounding vibrations to said support member, whereby said externally resounding vibrations are further prevented from traveling through a structure having said sound speaker stand positioned on.

2. The sound speaker stand, according to claim 1, wherein said dampening vibration means suspends said platform member relative to said support member.

3. The sound speaker stand, according to claim 1, wherein said predetermined shape of said support member includes a frame having a back side, a left side and a right side.

4. The sound speaker stand, according to claim 3, wherein said external vibration dampening means includes a plurality of wires, a plurality of first securing means for securing one end of each wire to said platform member and a plurality of second securing means for securing another end of said each wire to one of said left side and said right side of said frame.

5. The sound speaker stand, according to claim 4, wherein each of said plurality of first securing means includes:
(a) an aperture formed in said platform member;
(b) a bore which is axially aligned with said aperture and which is formed in a bottom surface of said platform member;
(c) an elongated member which is positioned within said bore and wherein said one end of said wire encircles said elongated member; and
(d) a swage clamp means for securing said encircled end.

6. The sound speaker stand, according to claim 5, wherein said each of said plurality of first securing means further includes a washer positioned between a bottom of said bore and said elongated member.

7. The sound speaker stand, according to claim 5, wherein said elongated member is formed of a material which is identical to said predetermined material of said support member.

8. The sound speaker stand, according to claim 4, wherein each of said plurality of second securing means includes:
(a) an aperture formed in said one of said left side and said right side of said support member;
(b) a bore which is axially aligned with said aperture and which is formed in at least one of said left side and said right side of said frame;
(c) an elongated member which is positioned within said bore and wherein said one end of said wire encircles said elongated member; and
(d) a swage clamp means for securing said encircled end.

9. The sound speaker stand, according to claim 8, wherein said each of said plurality of second securing means further includes a washer positioned between a bottom of said bore and said elongated member.

10. The sound speaker stand, according to claim 1, wherein said predetermined material for forming said support member is selected from wood, plastic, metal and any combinations thereof.

11. The sound speaker stand, according to claim 1, wherein said platform member is supported in a suspending fashion at positions that are closely adjacent each corner thereof.

12. The sound speaker stand, according to claim 1, wherein said sound speaker stand further includes means for dampening any internally resounding vibrations produced by the sound speaker.

13. The sound speaker stand, according to claim 12, wherein said internal vibration dampening means includes an aperture which is formed in said platform member and which is disposed beneath and is generally aligned with a bottom surface of the sound speaker.

14. The sound speaker stand, according to claim 1, wherein said platform member is formed of a material which is identical to said predetermined material of said support member.
